(19) United States
(12) Patent Application Publication
(10) Pub. No.: US 2010/0280670 A1
(43) Pub. Date: Nov. 4, 2010

(54) MAGNETIC FIELD SENSOR AND DISPENSER CONTROL SYSTEM

(75) Inventor: Robert W. Haul, St. Louis, MO (US)

Correspondence Address: HUSCH BLACKWELL LLP, 190 Carondelet Plaza, Suite 600, ST. LOUIS, MO, 63105, US

(73) Assignee: Robert W. Haul, St. Louis, MO (US)

(21) Appl. No.: 12/836,323

(22) Filed: Jul. 14, 2010

Related U.S. Application Data
(63) Continuation of application No. 11/368,560, filed on Mar. 6, 2006, now abandoned.

(51) Int. Cl. G05D 7/00; G01R 33/06

(52) U.S. Cl. 700/283; 324/251

(57) ABSTRACT

A dispenser control system for a washing machine having at least one electrically operated device includes a controller; at least one fluid transfer mechanism in communication with said controller and in fluid communication with said washing machine; a magnetic field sensor removably connected to an exterior housing of said electrically operated device, said connection made by a surface mount mechanical connector; and means for communicating a signal from said magnetic field sensor to said controller, said signal generated by said magnetic field sensor in response to detection by said sensor of a magnetic flux generated by said electrically operated device outside of said housing of said electrically operated device.

### CROSS REFERENCE

This application is a continuation of, and claims the priority of, co-pending application Ser. No. 11/368,560, filed Mar. 6, 2006.

### TECHNICAL FIELD OF THE INVENTION

The present invention relates generally to commercial ware wash and laundry machines and, more particularly, to an improved sensor for dispensers used with these machines.

### BACKGROUND OF THE INVENTION

Accessory dispensing systems for commercial washing machines, such as ware wash and laundry machines, are frequently provided as accessory items by commercial cleaning chemical supply companies to help promote their cleaning products. As such, these systems are installed onto washing machines that are already in place and in use. The washing machines are typically self-contained units but require manual addition of the required chemicals, like rinse agent or detergent, for every load. The accessory dispensing systems provide for automatic dispensing of these chemicals from bulk storage reservoirs for less “hands-on” operation. These washing machines typically have at least one electrical motor or electrically controlled solenoid valve that operate various functions, e.g., wash, rinse, dry cycles, of the machine. These electrically operated devices are controlled by the washing machine and, therefore, do not require outside control.

These accessory dispensing systems must directly or indirectly communicate with the washing machine in order to determine the appropriate time to transfer each particular required chemical to the washing machine. For example, the dispensing system must determine when a wash cycle is starting in order to trigger operation of the appropriate pump to transfer detergent to the machine. Similarly, the system must identify the beginning of a rinse cycle so that rinsing agent can be pumped into the washing machine at that time. The timing of the various cycles of these washing machines is typically indicated by the operation of specific motors or solenoid valves within the machine. Therefore, connecting the dispensing system to these specific motors and solenoid valves such that operation of these devices sends an electrical signal to the dispensing allows the system to determine the appropriate timing for transferring fluids.

Currently, these dispensing systems are connected to the electrical components of washing machines through a hard-wired connection to each electrical component. This requires substantial dismantling of the washing machines to access the motors and solenoid valve electrical connections. These installation requirements introduce several significant drawbacks to these systems. First, because the interiors of the machine's motors and solenoid valve wiring are exposed, the danger of electrocution is present. Second, in part due to the preceding danger, it is necessary to involve a skilled electrician for installation. In some facilities, the requirement of utilizing an electrician can be prohibitive in terms of the resulting time and expense. Furthermore, in some systems it is difficult to locate the proper electrical contacts.

The present invention is directed to overcoming one or more of the problems set forth above.

### SUMMARY OF THE INVENTION

An aspect of the present invention is to provide a means for controlling an accessory dispenser controller for commercial washing machines that eliminates the need for a hard-wired connection between the controller and the washing machine.

Another aspect of the invention is to provide a means for controlling an accessory dispenser controller for a washing machine that may be installed without the assistance of an electrician.

Yet another aspect of the invention is to provide an improved and safer method of installing a dispenser for a commercial washing machine.

In accordance with the above aspects of the invention, there is provided a dispenser control system for a washing machine having at least one electrically operated device that includes a controller; at least one fluid transfer mechanism in communication with the controller and in fluid communication with the washing machine; a magnetic field sensor removably connected to an exterior housing of the electrically operated device, the connection being made by a non-invasive mechanical connector; and means for communicating a signal from the magnetic field sensor to the controller, the signal generated by the magnetic field sensor in response to detection by the sensor of a magnetic flux generated by the electrically operated device outside of the housing of the electrically operated device.

In accordance with another aspect of the invention, there is provided a surface-mounted sensor for use with an accessory controller for electrically operated equipment that includes a surface mount mechanical connector; a housing adaptable for connection with said surface mount mechanical connector; a circuit board within said housing, said circuit board defining a flux field sensor; and means for communicating a signal from said circuit board to said accessory controller.

These aspects are merely illustrative of the various aspects associated with the present invention and should not be deemed as limiting in any manner. These and other aspects, features and advantages of the present invention will become apparent from the following detailed description when taken in conjunction with the referenced drawings.

### BRIEF DESCRIPTION OF THE DRAWINGS

Reference is now made to the drawings which illustrate the best known mode of carrying out the invention and wherein the same reference numerals indicate the same or similar parts throughout the several views.

FIG. 1 is a block diagram of a dispenser control system according to an embodiment of the present invention.

FIG. 2 is a perspective view of a dispenser control system according to another embodiment.

FIG. 3 is a plan view of a magnetic field sensor according to another embodiment for use in a dispenser control system.

FIG. 3A is a section view of the magnetic field sensor taken along line A-A of FIG. 3.

FIG. 4 is a plan view of a printed circuit board suitable for use in a magnetic field sensor according to another embodiment.

FIG. 5 is a circuit diagram for the printed circuit board of FIG. 4.

FIG. 6 is a block diagram of a dispenser control system incorporating a wirelessly operating magnetic field sensor.

### DETAILED DESCRIPTION

In the following detailed description, numerous specific details are set forth in order to provide a thorough understanding of the invention. However, it will be understood by those skilled in the art that the present invention may be practiced without these specific details. For example, well-known methods, procedures, and components have not been described in detail so as not to obscure the present invention.

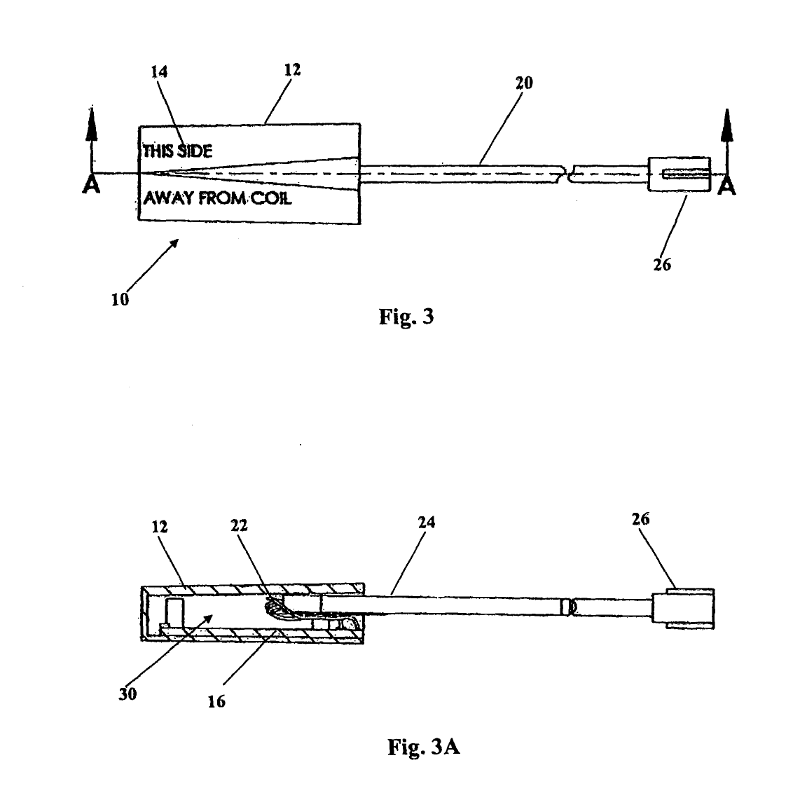

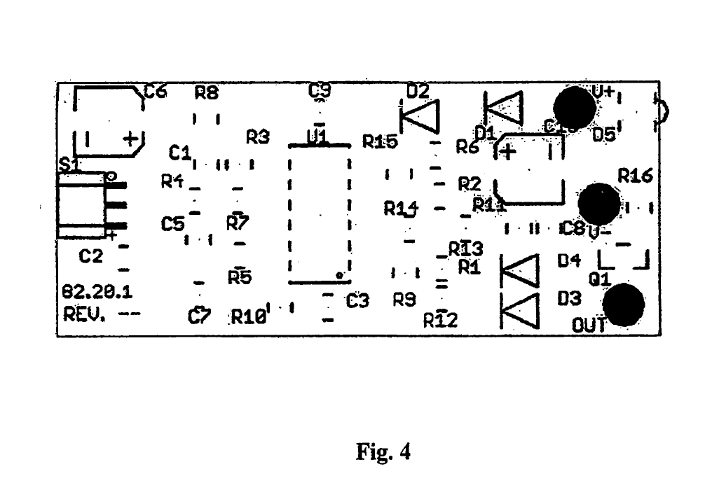

One embodiment of a magnetic field sensor 10 according to the present invention is illustrated in FIGS. 3 and 3A. The sensor 10 includes a housing 12, alternately referred to as a potting box. The housing 12 contains and protects the electronic components of the sensor 10, as well as providing a ready means for mounting the sensor where needed. In a preferred embodiment, the housing 12 is molded from a plastic material, such as polypropylene. The housing 12 is of a generally rectangular box shape, although the particular shape of the housing 12 is not central to the nature of the invention. The housing 12 is provided with one open end to allow for insertion of the sensor's electronic components. Depending on the manner in which the electronic components of the sensor 10 are mounted within the sensor 12, the performance of the housing may be enhanced by orienting the housing 12 in a specific manner relative to the device being monitored. For example, if the electronic components are mounted to one side of the housing 12, it is preferred to mount that side of the housing 12 against the exterior of the monitored device. This mounting preference may be clearly shown by a suitable alignment indicator 14 provided on the exterior surface of the housing 12. In the illustrated embodiment, the alignment indicator 14 takes the form of writing on the exterior surface of the housing 12 intended to indicate that the opposite side of the housing 12 should be mounted against the exterior of the monitored device and, in particular, against the housing of the device's electrical coil in the case of a solenoid valve.

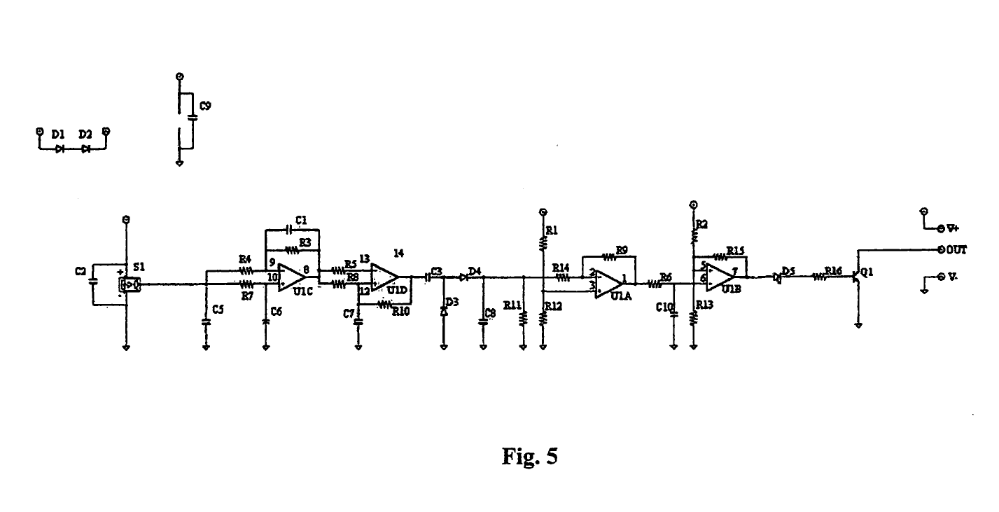

In one embodiment, the electronic portion of the sensor 10 includes a printed circuit board 16 containing the circuitry comprising a Hall Effect sensor, an amplifier, and a filter. These elements are known to those in the art. A circuit diagram for the illustrated embodiment is shown in FIG. 5. The components utilized in the printed circuit board 16 of the illustrated embodiment are as shown in the following table:

| No. | Quantity | Component | Description | Manufacturer |
|---|---|---|---|---|
| 1 | 3 | C1, C2, C9 | .01 uF 50 V X7R | |
| 2 | 3 | C3, C5, C7 | .1 uF 25 V X7R | |
| 3 | 2 | C6, C10 | 10 uF 35 V | |
| 4 | 1 | C8 | .22 uF 16 V X7R | |
| 5 | 4 | D1, D2, D3, D4 | 1N4148 | |
| 6 | 1 | D5 | LED-Green | Lumex |
| 7 | 3 | OUT, V+, V− | Spring Socket | Amp |
| 8 | 1 | Q1 | 2N3904 | |
| 9 | 3 | R1, R4, R12 | 10K 1/10 W 5% | |
| 10 | 1 | R10 | 470K 1/10 W 5% | |
| 11 | 1 | R16 | 2.2K 1/10 W 5% | |
| 12 | 6 | R2, R5, R7, R8, | 4.7K 1/10 W 5% | |
| | | R13, R15 | | |
| 13 | 2 | R3, R9, R11 | 1 M 1/10 W 5% | |
| 14 | 2 | R6, R14 | 100K 1/10 W 5% | |
| 15 | 1 | S1 | SS495A2SP | Honeywell |
| 16 | 1 | U1 | LM324D | |
| 17 | 1 | PWB | Printed Wiring | |
| | | | Panel | |

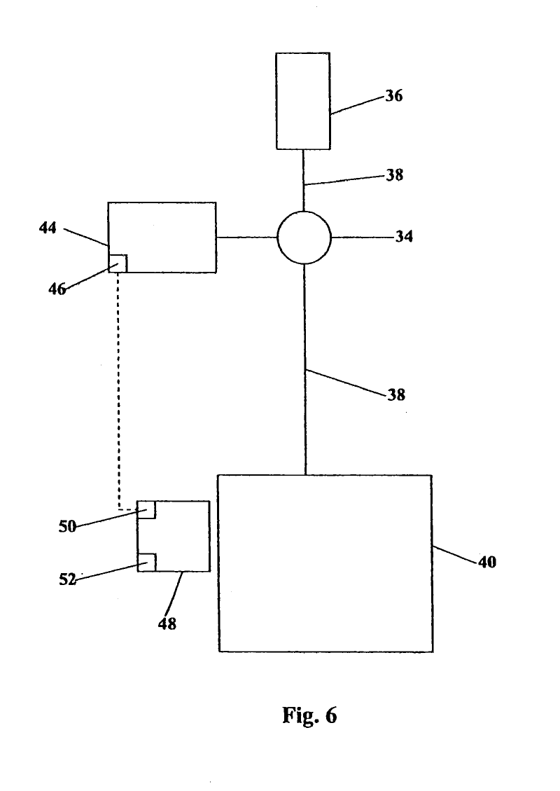

The printed circuit board 16 includes pin receptacles 18 to enable connection of the printed circuit board 16 to a cable assembly 20. The cable assembly 20, as shown in FIG. 6, advantageously includes three wires 22; one for power to the sensor, one return wire, and one for transmission of signals from the sensor. The wires 22 are preferably housed within a wiring jacket 24 for protection. At the controller end of the cable assembly 20, a quick connector 26 is provided with terminals for each wire in the assembly. While it is not essential to the present invention, the quick connector 26 does allow for simple plug-in installation to the dispenser controller.

During assembly of the sensor 10, the printed circuit board 16 is inserted into the housing 12. Wires 22 are inserted into the appropriate pin receptacle 18 on the printed circuit board 16. The housing 12 is then filled completely with a potting compound 30, such as a clear silicone, to further secure and protect the printed circuit board 16 and the connection between the PCB 16 and the cable assembly 20.

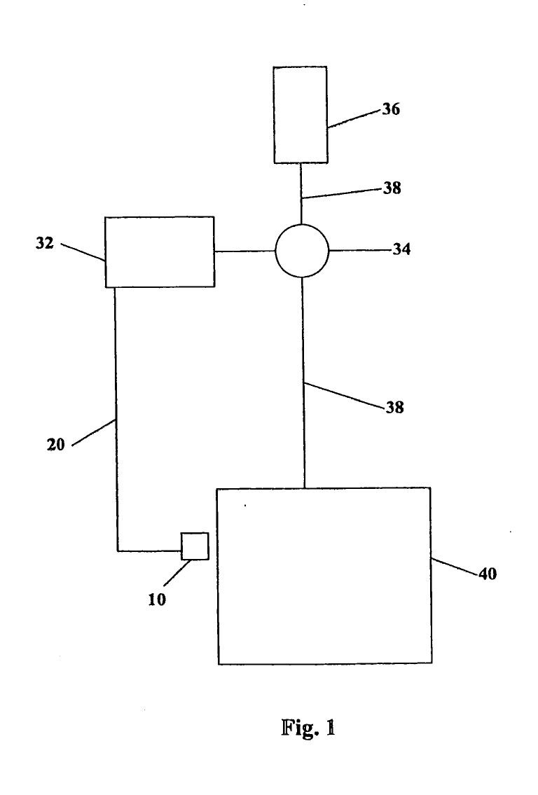

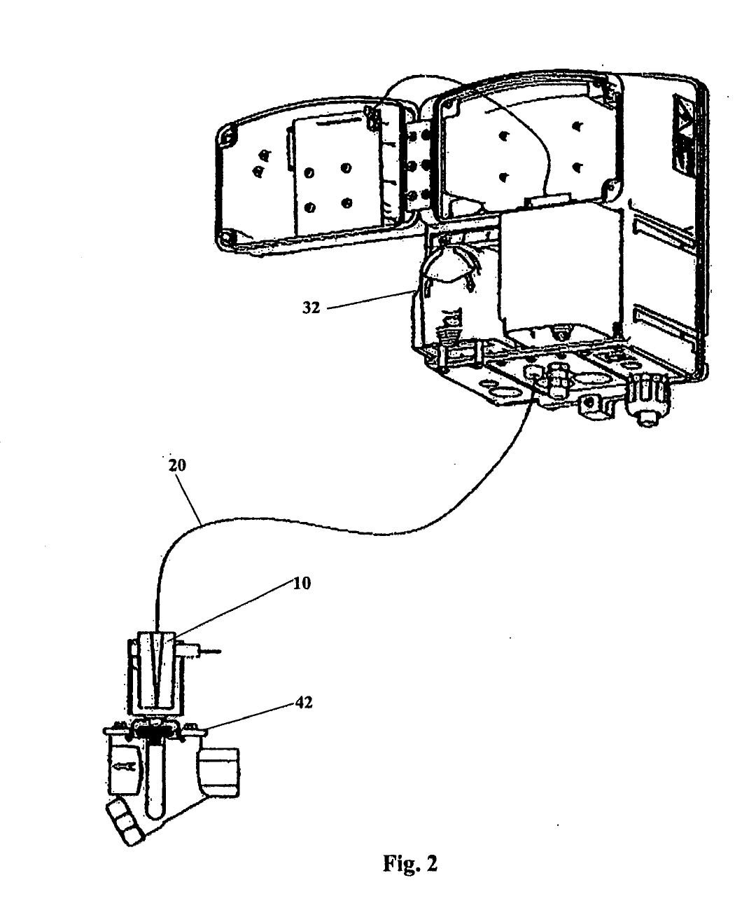

FIGS. 1 and 2 depict a dispenser system according to one embodiment incorporating a magnetic field sensor as previously described. The dispenser system includes a controller 32, at least one fluid pump, valve, or other fluid transfer mechanism 34, and at least one sensor 10. The pump is operative for drawing fluid, such as rinse agent or detergent, from a reservoir 36, and transferring the fluid via a supply line 38 to a washing machine 40, such as a commercial ware wash or laundry machine. The fluid may be supplied into a specific fluid inlet of the washing machine or directly into the machine's washing tank.

Dispensing systems as described herein are frequently provided as accessory items by commercial cleaning chemical supply companies to help promote their cleaning products. As such, these systems are installed onto washing machines that are already in place and in use. The washing machines are typically self-contained units but require manual addition of the required chemicals, like rinse agent or detergent, for proper cleaning. The accessory dispensing systems provide for automatic dispensing of these chemicals from bulk storage reservoirs for less “hands-on” operation. These washing machines typically have at least one electrical motor or electrically controlled solenoid valve that operate various functions, e.g., wash, rinse, dry cycles, of the machine. These electrically operated devices are controlled by the washing machine and, therefore, do not require outside control.

Accessory dispensing systems as described herein must directly or indirectly communicate with the washing machine in order to determine the appropriate time to transfer each particular required chemical to the washing machine. For example, the dispensing system must determine when a wash cycle is starting in order to trigger operation of the appropriate pump to transfer detergent to the machine. Similarly, the system must identify the beginning of a rinse cycle so that rinsing agent can be pumped into the washing machine at that time. The timing of the various cycles of these washing machines is typically indicated by the operation of specific motors or solenoid valves within the machine. Therefore, connecting the dispensing system to these specific motors and solenoid valves such that operation of these devices sends an electrical signal to the dispensing allows the system to determine the appropriate timing for transferring fluids.

Installation of the accessory dispensing systems described herein is accomplished by first mounting the dispenser controller 32 to a solid surface. Typically, the pump(s) 34 associated with the system are integrated with the controller 32. A first fluid supply line 38 is installed between a pump 34 and a respective fluid reservoir 36. A second supply line 38 is installed between each pump 34 and the washing machine 40. Next, each sensor 10 is connected to the controller 32 by means of the cable assembly 20. If a quick connector 26 is provided, the cable assembly 20 may simply plugged-in to a mating female connector on the controller 32. One sensor 10 is used for each relevant electrically operated valve or motor 42 in the washing machine. A typical ware wash application will require two sensors. Laundry dispensers may require multiple sensors. Each sensor 10 is connected to the exterior housing of its associated electrically operated device. Advantageously, the sensor need not be hard-wired into the electrically operated device. Simply mounting the sensor 10 to the exterior housing of the device, in particular, adjacent the electrical coils of the solenoid or motor, suffices. In a preferred embodiment, the sensor 10 is strapped to the housing of the electrically operated device with a hook and loop fastener. However, many other surface mounting arrangements, for example releasable adhesives, are perfectly suitable.

All of the controllable machine components on these washing machines operate on electromagnetic principles and, therefore, produce flux fields. Practical considerations of the design of these devices dictate that some portion of the flux field will leave the designed flux path. This stray flux will exist in a field surrounding the particular component. It will only be present when power is supplied to the solenoid or motor. The magnetic field sensor described herein detects stray flux fields around these electrically operated devices. It then converts this stray flux into an electrical signal that can be used to trigger operation of the dispenser. In the preferred embodiment, the sensor uses a Hall Effect sensor to sense the flux density in the vicinity of the sensor. The Hall Effect sensor produces an analog output proportional to the magnitude and polarity of the flux field surrounding it. This signal is then amplified and filtered to remove noise before it is transmitted to the controller.

In another preferred embodiment, the sensor can be tuned to detect any specific flux fields. In one embodiment, the sensor is tuned to respond to fields surrounding alternating currents in the 50 Hz to 60 Hz range. The “tuning” of the sensor is a sensitivity adjustment. The flux density to which the sensor responds is adjusted. Generally speaking, the flux density decreases by the square of the distance from the source. Limiting the sensitivity allows sensors to be applied to closely positioned independent flux sources. This requires close magnetic coupling of the sensor to the flux source (putting the sensor in the right place on the coil). The ability to tune the sensor eliminates false signals due to spurious noise from transients in the subject machine. It also eliminates false triggers from permanent magnets that may be in the vicinity of the sensor. The sensitivity of the sensor can be advantageously limited so that the sensor does not respond to nearby electromechanical components. In another embodiment, the sensor incorporates a visual indicating LED that indicates when the sensor is activated by a flux field. This feature eases proper positioning of the sensor on the respective motor or solenoid during initial installation. When properly positioned, the sensor will reliably indicate the operation of the subject device and provide electrical isolation from it.

While a wired version of the sensor has been previously described, the sensor may also be utilized in conjunction with wireless transmission of triggering signals to the dispenser controller. For example, radio frequency (RF) or infrared (IR) signals may be utilized. These transmission systems are well known in general, but have not been utilized in this capacity. In such a system, as illustrated in FIG. 6, the dispenser controller 44 is provided with a wireless signal receiver 46. The connections between the controller 44 and the pump(s) 34, reservoir 36, and supply lines 38 remain the same. Rather than a wired cable assembly, the wireless magnetic field sensor 48 is provided with a wireless transmitter 50. Because there is no electrical connection by which to supply the sensor 48 with power, the sensor 48 is also supplied with a power source 52, such as a battery pack. The remainder of the sensor 48 is essentially the same as its wired counterpart. The sensor 48 and controller 44 operate in the same manner as the wired version.

Other objects, features and advantages of the present invention will be apparent to those skilled in the art. While preferred embodiments of the present invention have been illustrated and described, this has been by way of illustration and the invention should not be limited except as required by the scope of the appended claims and their equivalents.

What is claimed is:

1. A dispenser control system for a washing machine, said washing machine having at least one electrically operated device, comprising:
a controller;
at least one fluid transfer mechanism in communication with said controller and in fluid communication with said washing machine;
a magnetic field sensor removably connected to an exterior housing of said electrically operated device, said connection made by a surface mount mechanical connector;
means for communicating a signal from said magnetic field sensor to said controller; and
wherein said magnetic field sensor is operable for generating said signal in response to detection by said sensor of a magnetic flux generated by said electrically operated device outside of said housing of said electrically operated device.

2. The dispenser control system as set forth in claim 1, wherein said electrically operated device is selected from a group consisting of a solenoid valve and an electrical motor.

3. The dispenser control system as set forth in claim 1, wherein said means for communicating a signal from said magnetic field sensor to said controller is an electrically wired connection.

4. The dispenser control system as set forth in claim 1, wherein said means for communicating a signal from said magnetic field sensor to said controller is a wireless connection.

5. The dispenser control system as set forth in claim 4, wherein said wireless connection is selected from a group consisting of a radio frequency transmitter and an infrared transmitter.

6. The dispenser control system as set forth in claim 1, wherein said magnetic field sensor is a Hall Effect sensor.

7. The dispenser control system as set forth in claim 1, wherein said magnetic field sensor is a Hall Effect switch.

8. The dispenser control system as set forth in claim 1, wherein said signal generated by said magnetic field sensor is proportional to a magnitude and polarity of the magnetic flux sensed by the magnetic field sensor.

9. The dispenser control system as set forth in claim 1, wherein said magnetic field sensor further comprises an amplification circuit and a filter circuit to amplify and filter said signal before said signal is communicated to said controller.

10. The dispenser control system as set forth in claim 1, wherein said magnetic field sensor further comprises means for tuning said magnetic field sensor to detect a specified flux field range.

11. The dispenser control system as set forth in claim 1, wherein said magnetic field sensor further comprises a visual indicator that is activated when said magnetic field sensor detects a magnetic flux field.

12. The dispenser control system as set forth in claim 1, wherein said magnetic field sensor further comprises:
a housing;
a circuit board within said housing; and
wherein said means for communicating is in operative communication with said circuit board and is selected from the group comprising:
a wired cable assembly;
a radio frequency transmitter; and
an infrared transmitter.

13. The dispenser control system as set forth in claim 12, wherein said circuit board further comprises an amplification circuit and a filter circuit.

14. A dispenser control system for a washing machine, said washing machine having at least one electrically operated device, comprising:
a controller;
at least one fluid transfer mechanism in communication with said controller and in fluid communication with said washing machine;
a magnetic field sensor removably connected to an exterior housing of said electrically operated device, said magnetic field sensor further comprising:
a surface mount mechanical connector;
a housing adaptable for connection with said surface mount mechanical connector;
a circuit board within said housing, said circuit board defining a Hall Effect sensor, an amplification circuit, and a filter circuit; and
means for communicating an analog output signal from said magnetic field sensor to said controller, said analog output signal generated by said magnetic field sensor in response to detection by said sensor of a magnetic flux generated by said electrically operated device outside of said housing of said electrically operated device, said means for communicating selected from the group comprising:
a wired cable assembly;
a radio frequency transmitter; and
an infrared transmitter.

15. A method for controlling a dispenser for a washing machine, said washing machine having at least one electrically operated device, comprising the steps of:
installing a controller;
providing at least one fluid transfer mechanism in communication with said controller and in fluid communication with said washing machine;
removably connecting a magnetic field sensor to an exterior housing of said at least one electrically operated device with a surface mount mechanical connector; and
transmitting a signal from said magnetic field sensor to said controller upon detection by said magnetic field sensor of a magnetic flux field generated by said at least one electrically operated device.
triggering operation of said at least one fluid transfer mechanism by said dispenser controller upon receiving said output signal, wherein operation of said at least one fluid transfer mechanism transfers fluid from said fluid reservoir to said washing machine via said fluid connection.

16. The method for controlling a dispenser for a washing machine as set forth in claim 15, wherein said step of transmitting a signal from said magnetic field sensor to said controller further comprises amplifying and filtering said output signal prior to transmission.

17. The method for controlling a dispenser for a washing machine as set forth in claim 15, further comprising the step of tuning said magnetic field sensor to detect a specified flux field range prior to attaching said magnetic field sensor to said exterior housing of said at least one electrically operated device.

18. The method for controlling a dispenser for a washing machine as set forth in claim 15, wherein said step of transmitting a signal further comprises converting said signal to a radio frequency signal for wireless transmission to said controller.

19. The method for controlling a dispenser for a washing machine as set forth in claim 15, wherein said step of transmitting a signal further comprises converting said signal to an infrared signal for wireless transmission to said dispenser controller.

20. The method for controlling a dispenser for a washing machine as set forth in claim 15, further comprising the step of triggering operation of said at least one fluid transfer mechanism by said controller upon receiving said signal.
